(19) United States
(12) Patent Application Publication
(10) Pub. No.: US 2016/0322262 A1
(43) Pub. Date: Nov. 3, 2016

(54) INTEGRATION OF DEVICES

(71) Applicant: GLOBALFOUNDRIES Singapore Pte. Ltd., Singapore (SG)

(72) Inventors: Ming LI, Singapore (SG); Jeoung Mo KOO, Singapore (SG); Purakh Raj VERMA, Singapore (SG)

(21) Appl. No.: 14/698,883

(22) Filed: Apr. 29, 2015

(51) Int. Cl. H01L 21/8234; H01L 29/06; H01L 21/265; H01L 29/78; H01L 21/306; H01L 21/321; H01L 29/40; H01L 29/66; H01L 21/762; H01L 29/10

(52) U.S. Cl. CPC H01L 21/823481; H01L 21/76224; H01L 29/0649; H01L 21/26513; H01L 29/1079; H01L 21/30604; H01L 21/26586; H01L 21/3212; H01L 29/404; H01L 29/407; H01L 29/0638; H01L 29/66568; H01L 29/78

(57) ABSTRACT

Devices and methods for forming a device are presented. A substrate with lightly doped first polarity type dopants is provided. A buried layer with heavily doped second polarity type dopants is formed in a top portion of the substrate. An epitaxial layer is formed over the buried layer. Deep trench isolation (DTI) regions which extend from top surface of the epitaxial layer to a portion of the substrate are formed. The DTI regions isolate different buried regions defined in the buried layer. Sinker tap regions which at least partially surround sides of the DTI regions and extend from the epitaxial layer into a portion of the buried layer are formed. The sinker tap region connects sinker taps to the buried layer. Shallow trench isolation (STI) regions are formed in the epitaxial layer. At least one transistor is formed on the epitaxial layer,

### BACKGROUND

As technology evolves into era of sub-micron, there is a desire to integrate memory array, high voltage (HV) devices and high speed logic circuit elements into a single chip or integrated circuit (IC) to form an embedded device. Nevertheless, it is difficult to integrate these different types of devices in a single chip since interference is prone to occur between the different devices. For example, high voltage devices may have latch up problem. This may undesirably affect the reliability of the overall product during integration. As such, there is a need to properly isolate the different types of devices from each other during integration. However, the use of various isolation structures to properly isolate the different types of devices may complicate the manufacturing process and require additional masking step which increases the manufacturing cost.

From the foregoing discussion, it is desirable to provide a reliable, high performing, simplified and cost effective solution to integrate various suitable isolation structures to properly isolate HV, high speed logic and memory devices in the same IC.

### SUMMARY

Embodiments generally relate to semiconductor devices and methods of forming thereof. In one embodiment, a method for forming a device is presented. A substrate with lightly doped first polarity type dopants is provided. A buried layer with heavily doped second polarity type dopants is formed in a top portion of the substrate. An epitaxial layer is formed over the buried layer. Deep trench isolation (DTI) regions which extend from top surface of the epitaxial layer to a portion of the substrate are formed. The DTI regions isolate different buried regions defined in the buried layer. Sinker tap regions which at least partially surround sides of the DTI regions and extend from the epitaxial layer into a portion of the buried layer are formed. The sinker tap region connects sinker taps to the buried layer. Shallow trench isolation (STI) regions are formed in the epitaxial layer. At least one transistor is formed on the epitaxial layer.

In another embodiment, a device is disclosed. The device includes a substrate with lightly doped first polarity type dopants. A buried layer with heavily doped second polarity type dopants is disposed in a top portion of the substrate. An epitaxial layer is disposed over the buried layer. The device includes deep trench isolation (DTI) regions which extend from top surface of the epitaxial layer to a portion of the substrate. The DTI regions isolate different buried regions defined in the buried layer. The device also includes sinker tap regions which at least partially surround sides of the DTI regions and extend from the epitaxial layer into a portion of the buried layer. The sinker tap region connects sinker taps to the buried layer. Shallow trench isolation (STI) regions are disposed in the epitaxial layer. At least one transistor is disposed on the epitaxial layer.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following:

FIGS. 1a-1d show various embodiments of a portion of a device;

FIGS. 2a-2i show an embodiment of a process for forming a device;

FIGS. 3a-3b show another embodiment of a process for forming a device;

FIGS. 4a-4f show another embodiment of a process for forming a device; and

FIGS. 5a-5b show yet another embodiment of a process for forming a device.

### DETAILED DESCRIPTION

Embodiments generally relate to semiconductor devices or integrated circuits (ICs). More particularly, some embodiments relate to devices having high power devices integrated with logic and memory devices on the same substrate. For example, high power devices include lateral double-diffused metal oxide semiconductor (LDMOS) transistors. Other suitable high power devices may also be useful. The high power devices can be employed as switching voltage regulators for power management applications. The embodiments in the present disclosure relates to providing deep trench isolation (DTI), together with buried layer, (e.g., N+ buried layer (NBL)) and N-sinker to properly isolate the high power, logic and memory devices in the same IC without requiring additional masking step. Such devices can be incorporated into ICs and easily integrated into logic processing technologies without compromising the reliabilities of the different devices. The devices or ICs can be incorporated into or used with, for example, consumer electronic products, standalone memory devices, such as USB or other types of portable storage units, or ICs, such as microcontrollers or system on chips (SoCs) or other suitable types of products.

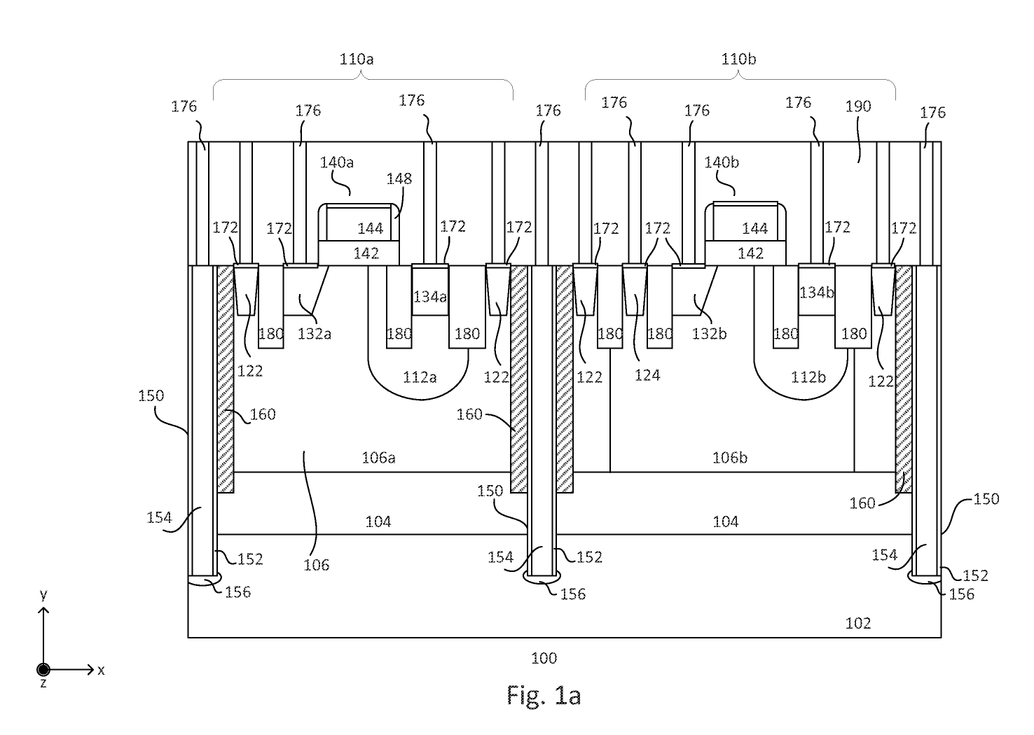

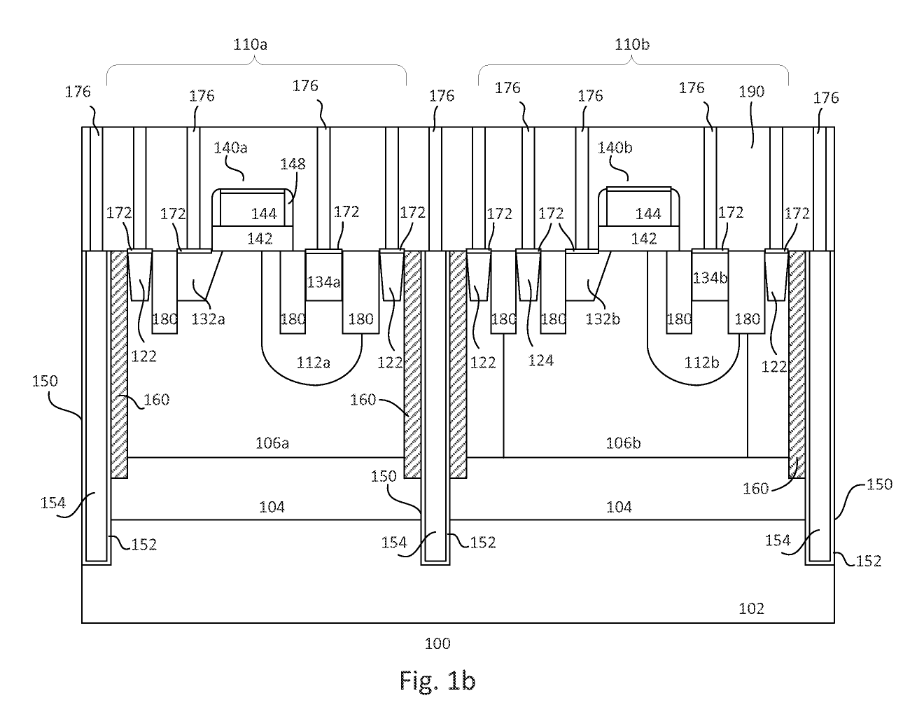

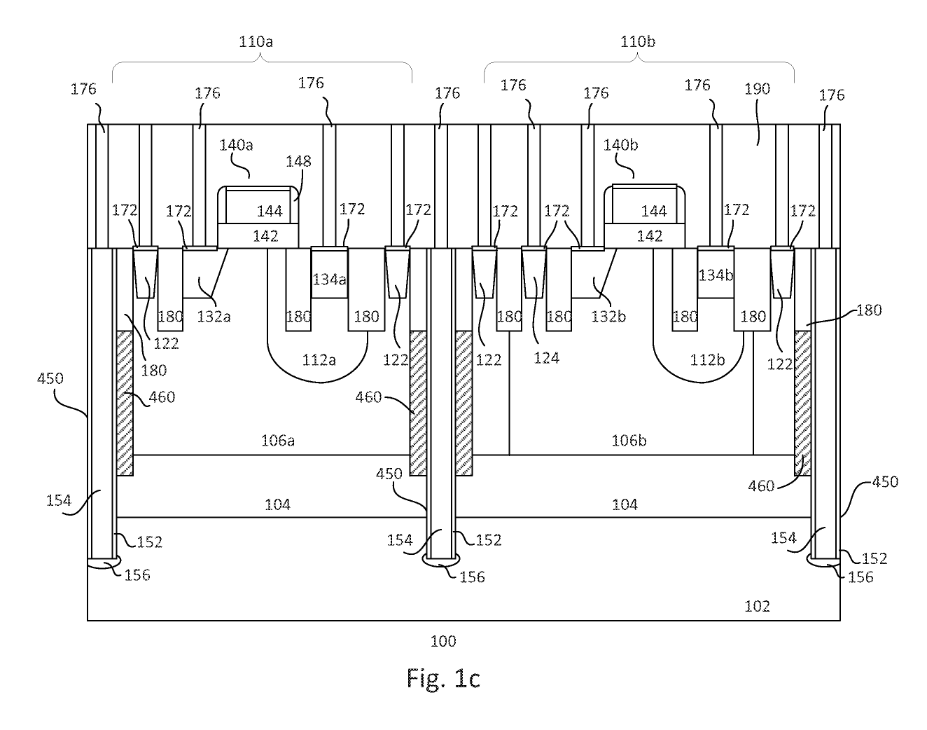

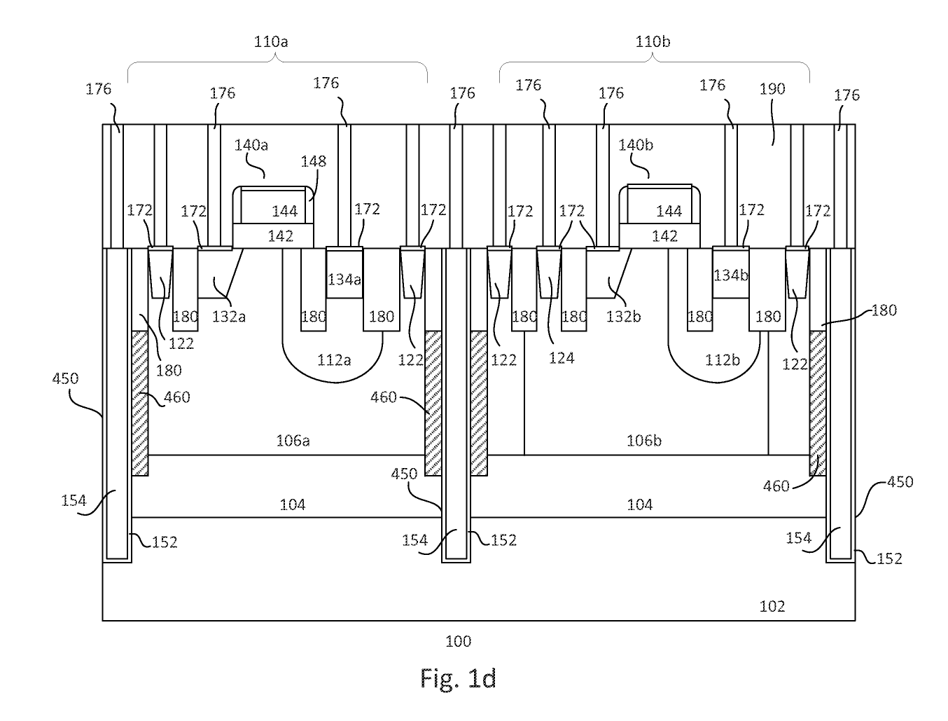

FIGS. 1a-1d show cross-sectional views of portions of different embodiments of a device 100. The device, for example, is an IC. Other types of devices may also be useful. As shown, the device includes a substrate 102. The substrate, for example, is a silicon substrate. Other suitable types of semiconductor substrates may also useful. The substrate maybe a doped substrate. For example, the substrate can be lightly doped with first polarity type dopants. The first polarity type dopants, for example, are p-type dopants. Providing a substrate with other types of dopants or dopant concentrations as well as an undoped substrate, may also be useful.

The device may include doped regions having different dopant concentrations. For example, the device may include heavily doped (x⁺), intermediately doped (x) and lightly doped (x⁻) regions, where x is the polarity type which can be p or n. A lightly doped region may have a dopant concentration of about 1E11-1E13/cm², and an intermediately doped region may have a dopant concentration of about 1E13-1E14/cm², and a heavily doped region may have a dopant concentration of about 1E14-1E17/cm². Providing other dopant concentrations for the different doped regions may also be useful. P-type dopants may include boron (B), aluminum (Al), indium (In) or a combination thereof, while n-type dopants may include phosphorous (P), arsenic (As), antimony (Sb) or a combination thereof.

A buried layer 104 is disposed in a top portion of the substrate 102 which is doped with first polarity type dopants and an epitaxial layer 106 is disposed over the buried layer. The top surface of the epitaxial layer may be referred to as a top surface of the substrate. Device wells 106a and 106b are defined in the epitaxial layer as will be described later. The buried layer, for example, is disposed in between the substrate 102 and the epitaxial layer. The buried layer, for example, is a heavily doped region with second polarity type dopants for a first polarity type substrate. For example, the buried layer is a n-type buried layer for a p-type substrate. The buried layer 104 includes n-type dopants and the dopant concentration of the buried layer is higher than the dopant concentration of the device wells. For example, the dopant concentration of the buried layer may be, for example, about 1E15-1E16/cm². The depth of the buried layer is, for example, about 1-5 μm. Other suitable dopant concentration and depth dimensions for the buried layer may also be useful. The buried layer, for example, is used for high voltage device isolation to the first polarity type substrate 102. As for the epitaxial layer, it is provided as a second polarity type epitaxial layer. For example, the epitaxial layer is a n-type epitaxial layer grown on the n-type buried layer. Alternatively, the epitaxial layer is a p-type epitaxial layer grown on the n-type buried layer. The dopant concentration of the epitaxial layer 106 is higher than the dopant concentration of the substrate 102. The dopant concentration of the epitaxial layer may be, for example, about 1E11-1E13/cm². The thickness of the epitaxial layer is, for example, about 5-15 μm. Other suitable dopant concentration and thickness dimensions for the epitaxial layer may also be useful.

The substrate includes at least one device region. The device region, for example, is a high voltage (HV) device region for high voltage devices, such as HV transistors. The HV device region, in one embodiment, includes first sub-region 110a and second sub-region 110b. Other suitable number or types of regions or sub-regions may also be included in the HV device region. The first sub-region, for example, includes a first polarity type lateral double-diffused metal oxide semiconductor (LDMOS) transistor 140a while the second sub-region includes a second polarity type LDMOS transistor 140b. For example, the first polarity type LDMOS is a LDPMOS transistor while the second polarity type LDMOS is a LDNMOS transistor. Other suitable high voltage devices may also be useful. The first and second sub-regions are prepared for devices operating in high voltage ranges, for example, at a voltage of about 30 V. Other suitable voltage values may also be useful.

The substrate is also prepared with other suitable types of regions (not shown) for other types of circuitry, depending on the type of device or IC. For example, the substrate may include regions for intermediate or medium voltage (MV) and low voltage (LV) devices as well as an array region for memory devices. For simplicity and illustration purpose, only the high voltage device region is shown.

Isolation regions may be provided for isolating or separating different doped regions of the substrate. In one embodiment, the different doped regions are isolated from each other by a shallow trench isolation (STI) region 180. A STI region includes an isolation trench filled with isolation or dielectric materials. Other suitable types of isolation regions may also be employed. The STI regions, for example, extend to a depth of, for example, about 2000-5000 Å from the top surface of the substrate. Providing isolation regions which extend to other suitable depths may also be useful.

As described, the HV transistors, for example, include LDMOS transistors. Other suitable types of HV transistors may also be useful. For illustration purpose, LDMOS transistors are described herein. A LDMOS transistor includes a gate on the surface of the substrate. The gate, for example, traverses the device region along the z direction. The width of the gate along a channel length direction of the transistor may be, for example, about 2-150 μm. As shown, the channel direction is in the x direction. The x and z directions, for example, are orthogonal directions. The gate, in one embodiment, includes a gate electrode 144 over a gate dielectric 142. The gate dielectric, for example, may be silicon oxide while the gate electrode may be polysilicon. The gate dielectric may be a high voltage gate dielectric having a thickness of, for example, about 60-1000 Å while the thickness of the gate electrode may be, for example, about 700-5000 Å. In some embodiments, the gate electrode may be a doped electrode. For example, n-type dopants may be used to dope the gate electrode of NMOS transistor while p-type dopants may be used to dope the gate electrode of PMOS transistor. Other suitable types of gate dielectrics and gate electrodes as well as thicknesses may also be useful.

The LDMOS transistor also includes first and second doped regions disposed in the substrate on first and second sides of the gate. For example, the first doped region is disposed on the first side of the gate and the second doped region is disposed on the second side of the gate. For a first type LDMOS transistor, the doped regions, in one embodiment, are heavily doped with first polarity type dopants. As for the second type LDMOS transistor, the doped regions, in one embodiment, are heavily doped with second type dopants. For example, the LDPMOS in the first sub-region 110a includes first and second doped regions 132a and 134a which are heavily doped p-type (p⁺) regions while the LDNMOS in the second sub-region 110b includes first and second doped regions 132b and 134b which are heavily doped n-type (n⁺) regions. The heavily doped regions, for example, have a dopant concentration of, for example, about 1E15-1E16/cm². Other suitable dopant concentrations for the doped regions may also be useful. The depth of the doped regions may be, for example, about 0.1-0.4 μm from the top surface of the substrate. Providing doped regions having other suitable depths may also be useful. Additionally, it is not necessary that the first and second doped regions have the same depth.

In one embodiment, the first doped region 132a or 132b serves as a source region while the second doped region 134a or 134b serves as a drain region of the LDMOS transistor. The source region is adjacent to the first side and underlaps the gate. The underlap portion should be sufficient for the source region to be in communication with the channel under the gate. The drain region is adjacent to the second side of the gate and is displaced away from the second side of the gate by an internal isolation region 180 as will be described later.

Sidewalls of the gate may be provided with dielectric spacers 148. The dielectric spacers, for example, may be silicon oxide spacers. Other suitable types of dielectric materials may also be useful, such as silicon nitride or a combination of dielectric materials or layers. For example, the spacers may be composite spacers. The spacers may include an offset spacer and main spacer. The offset spacers may facilitate forming the lightly doped diffusion regions (not shown) while the main spacers facilitate forming heavily doped source and drain regions. Other configurations of spacers may also be useful. For example, the spacer may be a single spacer. The lightly doped diffusion region is formed prior to forming the spacers while the spacers facilitate forming the heavily doped source and drain regions. In some cases, the LDMOS transistor may include a halo region. The halo region is a second polarity doped region abutting the source region proximate to the gate.

In one embodiment, an internal isolation region 180 is provided within the sub-regions of the HV device region. The internal isolation region may be a STI region. Other suitable types of isolation regions may also be useful. The internal isolation region, for example, is disposed in the device region along the z direction between the gate and drain. The internal isolation region, for example, extends from one side to the other side of the device region along the z direction. Other configurations of the internal isolation region may also be useful. As shown, the internal isolation region underlaps the gate and displaces the drain region away from the second side of the gate. For example, the internal isolation region extends under the second side of the gate by suitable dimension. Providing the internal isolation region which underlaps the gate protects the edge of the gate dielectric from high electric field during operation. The width of the internal isolation region, for example, may be about 0.5-10 μm. Other suitable widths may also be useful, depending on the drain voltage. The width and depth of the internal isolation region may determine a drift length of the transistor.

Drift wells are disposed in first and second sub-regions of the HV device region. For example, a drift well 112a or 112b is disposed between the gate and the drain region, under-lapping a portion of the gate. As shown, the drift well encompasses the drain and the internal device isolation region. In one embodiment, the depth or bottom of the drift well is below the drain region. In one embodiment, the depth or bottom of the drift well is below the STI and internal device isolation regions. In one embodiment, the drift well is contiguous and encompasses the drain region and at least overlaps a portion of the active region underneath the gate. The distance from the drain and around the internal isolation region to the channel under the gate is the drift distance of the transistor.

The drift well includes same polarity type dopants as the type of the transistor. For example, the drift well 112a in the first sub-region 110a includes first polarity type dopants, such as p-type dopants for LDPMOS while the drift well 112b in the second sub-region 110b includes second polarity type dopants, such as n-type dopants for LDNMOS. In one embodiment, the dopant concentration of the drift well is lower than the dopant concentration of the drain. In one embodiment, the drift well may be lightly (x⁻) or intermediately (x) doped with suitable polarity type dopants. For example, the dopant concentration of the drift well is, for example, about 1E12-1E14/cm². Other suitable dopant concentrations may also be useful. For example, the dopant concentration may depend on the maximum or breakdown voltage requirement of the device. The depth of the drift well may be, for example, about 0.5-5 μm depending on the design voltage of the device.

Device wells are disposed in the substrate. As described, the device wells are defined in the epitaxial layer. A device well, for example, encompasses the source, drain, drift well and internal device isolation region. The depth or bottom of the device well, for example, is below the source, drain and drift well. For example, the depth or bottom of the device well is below the STI regions and the drift well. Providing a device well which is shallower than or at the same depth as the drift well may also be useful. Other configurations of the device and drift well may also be useful.

A device well includes second polarity dopants for a first polarity type device. For example, the first device well 106a includes n-type dopants for a p-type transistor while the second device well 106b includes p-type dopants for a n-type transistor. The second device well 106b, for example, is disposed within the first device well 106a in the second sub-region. A depth of the second device well is the same as the first device well. Other configurations of the second device well may also be useful. The dopant concentration may depend on the voltage requirement of the device. The device well may be lightly (x⁻) or intermediately (x) doped with different polarity type of dopants than that of the type of the transistor. The dopant concentration of the device well is, for example, about 1E12-1E14/cm². Other suitable dopant concentration for the device well, for example, dopant concentration greater than that of the lightly doped substrate, may also be useful.

The first and second device wells, for example, are provided with first and second well contacts 122 and 124 respectively for biasing the wells. The well contacts are heavily doped regions, similar to the source/drain (S/D) regions. For example, a depth of the well contact is shallower than a depth of the STI region and the well contacts are in communication with the respective wells. The dopant concentration of the well contacts may be, for example, about 1E15-9E15/cm². The well contacts have the same polarity type as the respective wells. For example, the first well contact 122 is a second polarity type doped region and the second well contact 124 is a first polarity type doped region.

In one embodiment, deep trench isolation (DTI) regions or structures 150 are provided for isolating or separating different regions of the substrate. For example, the DTI regions are provided to isolate the first sub-region from the second sub-region and to isolate the HV device region from other regions of the substrate and to isolate different regions in the buried layer. The DTI regions provide lateral isolation of each device region. In one embodiment, the DTI regions extend from the top surface of the epitaxial layer 106 and extend into a portion of the first polarity type substrate 102. The bottom of the DTI region, for example, is below a top surface of the first polarity type substrate 102. The DTI regions, for example, extend to a depth of about 10-30 μm from the top surface of the epitaxial layer. For example, the DTI region extends to a depth of about 28 μm. Other suitable depth dimensions may also be useful.

The DTI region is filled with a conducting material 154 and a dielectric layer 152 lining at least sidewalls of the DTI region. In one embodiment, the dielectric layer lining sidewalls of the DTI region includes silicon oxide while the conducting material includes highly p-type doped polysilicon. The DTI region with highly p-type doped polysilicon, as shown, can connect with the first polarity or p-type substrate with low resistivity and to serve as substrate tap on silicon surface. A channel stop region 156 may optionally be disposed at the bottom of the DTI region as shown in FIG. 1a. The channel stop region, for example, provides better conductivity between the conducting material 154 of the DTI region and the first polarity type substrate 102. The channel stop region, for example, includes p-type dopants with concentration of about 1E15-1E16/cm². Other suitable concentration may also be useful. In an alternate embodiment, the bottom of the DTI regions is devoid of channel stop region an d the dielectric liner lines both sidewalls and bottom of the DTI region as shown in FIG. 1b. In such case, additional substrate tap (not shown) needs to be separately formed at other area by suitable implant.

In one embodiment, sinker tap regions 160 are disposed in the substrate. The sinker tap region 160, in one embodiment, at least partially surrounds the DTI regions. As shown in Figs, la and lb, the sinker tap regions extend from the top surface of the epitaxial layer 106 and extend into a portion of the buried layer 104. The bottom of the sinker tap region, for example, is below a top surface of the buried layer. Thus, the sinker tap region is electrically connected to the buried layer. The sinker tap regions, as shown, are disposed in between the DTI regions and the well contact 122. The sinker tap regions, for example, are second polarity type sinker tap regions for second polarity type buried layer. For instance, the sinker tap regions are n-type sinker tap regions for n-type buried layer. The sinker tap regions, for example, extend to a depth of about 5-15 μm. For example, the sinker tap region extends to a depth of about 7 μm. Other suitable depth dimensions may also be useful. The sinker tap region, as shown, can connect with the buried layer with low resistivity and to serve as buried layer tap on silicon substrate surface.

As described, the DTI regions 150 and the sinker tap regions 160 extend from the top surface of the substrate or epitaxial layer and pass through the epitaxial layer. The sinker tap regions, as shown in FIGS. 1a and 1b at least partially surround the DTI regions and extend from the top surface to a portion of the buried layer. In an alternate embodiment, the DTI regions 450 extend from a top surface of a STI region 180 and pass through the STI region while the sinker tap regions 460 at least partially surround the DTI regions and extend from a bottom of the STI region to a portion of the buried layer as shown in FIGS. 1c and 1d. As shown in FIG. 1c, a channel stop region is optionally provided at the bottom of the DTI region while the bottom of the DTI region is devoid of a channel stop region and the dielectric layer 152 lines both sidewalls and bottom of the DTI region as shown in FIG. 1d.

The provision and configuration of the DTI regions, sinker tap regions, the buried layer and the epitaxial layer provide advantages. For example, the buried layer and the DTI regions are used to avoid punch-through breakdown. Moreover, the configuration of these regions and layers effectively avoid latch up problem and effectively isolate the high voltage LDMOS transistors from other device regions. Also, the sinker tap region can also serve as drain pick-up if vertical double-diffused MOS (VDMOS) is integrated into IC.

Metal silicide contacts 172 may be provided on terminals or contact regions of the LDMOS transistors in the HV device region and transistors in other device regions. For example, metal silicide contacts may be provided on the gate electrode, S/D regions and well contacts. The silicide contacts, for example, may be nickel-based silicide contacts. Other suitable types of metal silicide contacts may also be useful. For example, the metal silicide contact may be cobalt silicide (CoSi). The silicide contacts may be, for example, about 50-300 Å thick. Other suitable thickness of silicide contacts may also be useful. The silicide contacts may be employed to reduce contact resistance and facilitate contact to the back-end-of-line metal interconnects.

A dielectric layer 190 is disposed on the substrate, covering the transistors and top of the substrate. The dielectric layer, in one embodiment, serves as a pre-metal dielectric (PMD) layer. The dielectric layer, for example, is a silicon oxide layer. In one embodiment, the dielectric layer is a high aspect ratio process (HARP) dielectric material. Other suitable types of dielectric materials are also useful. For example, the dielectric layer can be formed from doped silicon oxide such as fluorinated silicon oxide (FSG), undoped or doped silicate glasses such as boron phosphate silicate glass (BPSG) and phosphate silicate glass (PSG), undoped or doped thermally grown silicon oxide, undoped or doped TEOS deposited silicon oxide, and low-k or ultra low-k dielectric materials such as organo-silicate glass (OSG) and fluorine-doped silicate glass (FSG).

The PMD layer includes contacts 176 coupled to contact regions of the transistor. For example, contacts plugs 176 are provided in the PMD layer to the gate electrode (not shown), S/D regions and well contacts as shown in FIGS. 1a-1d. The contact plugs, for example, may be tungsten contact plugs. Other suitable types of conductive contact plugs may also be useful.

An inter-metal dielectric (IMD) layer (not shown) may be provided over the PMD layer. The IMD layer, for example, may be silicon oxide. Other types of IMD dielectric materials may also be useful. An etch stop layer may be provided between the IMD and PMD layers. The IMD layer may include conductive lines disposed in the IMD layer which interconnect to the contact plugs. Other configurations of IMD and PMD layers may also be useful.

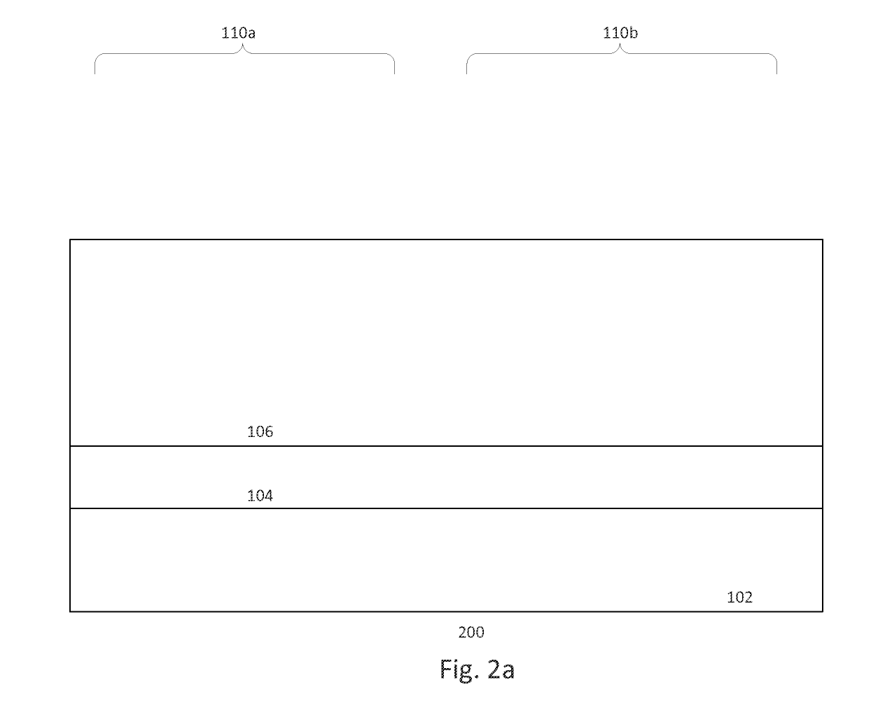

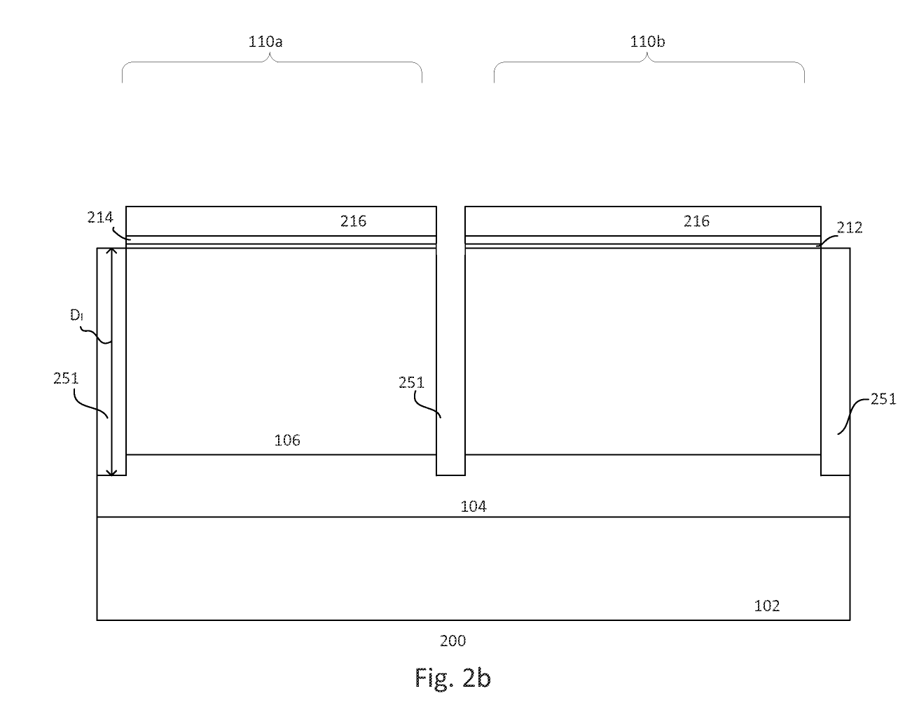

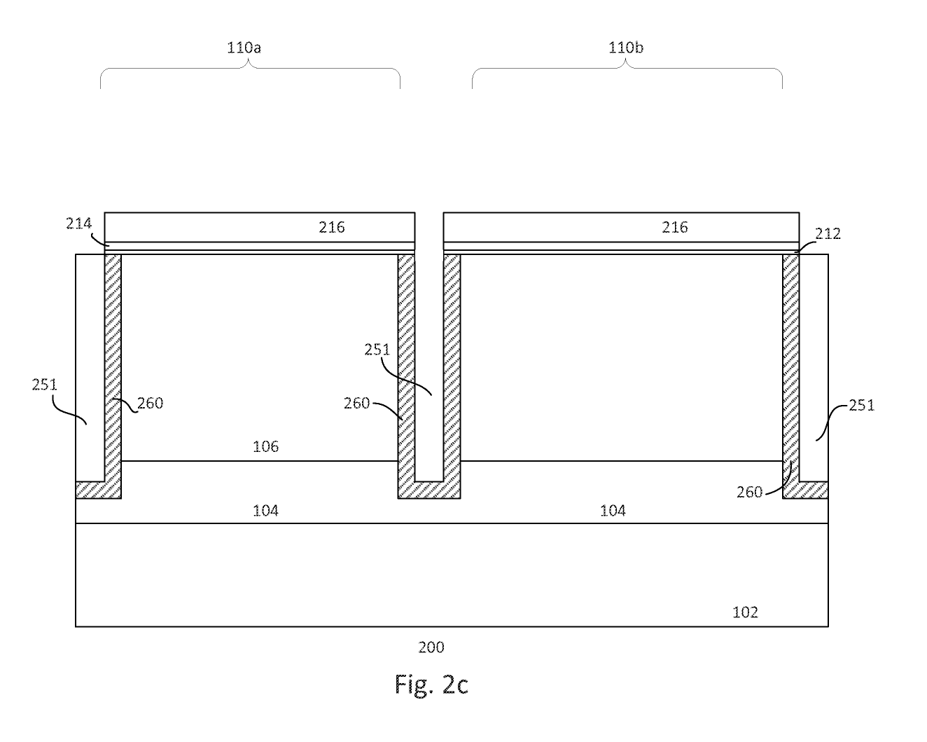

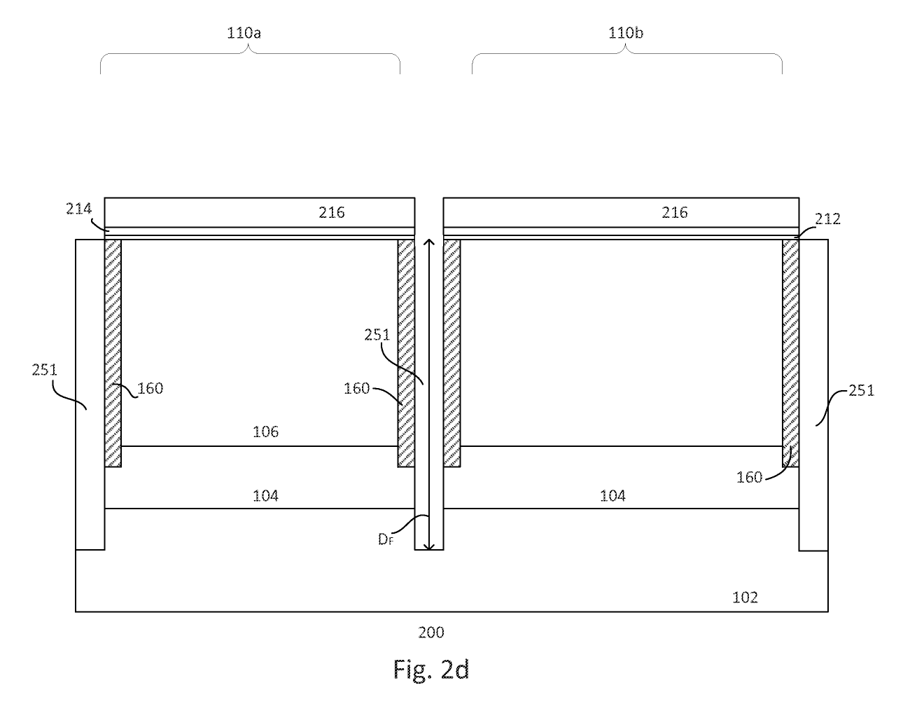

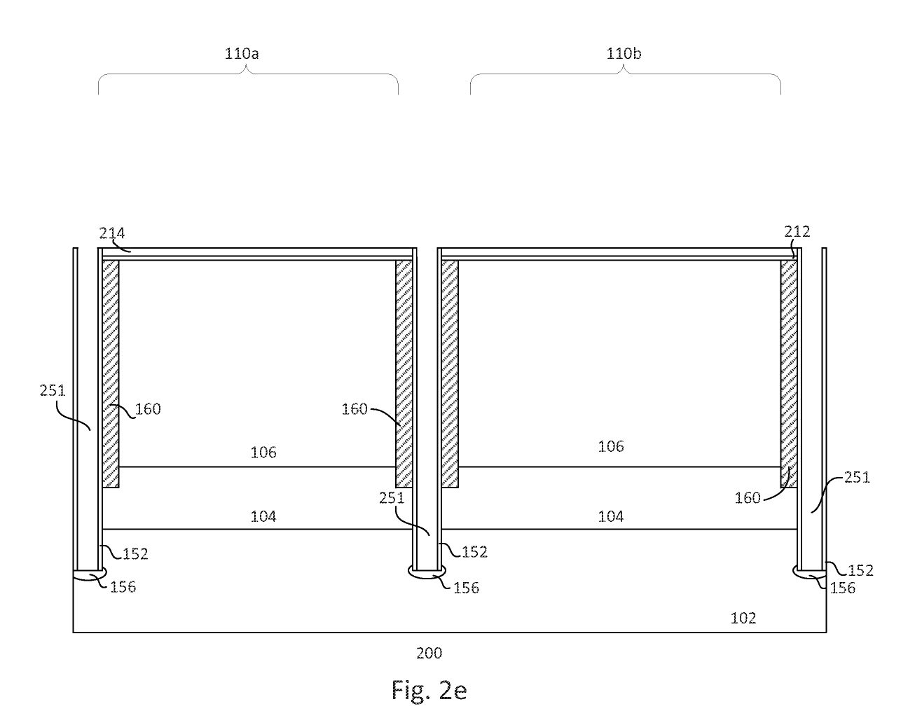

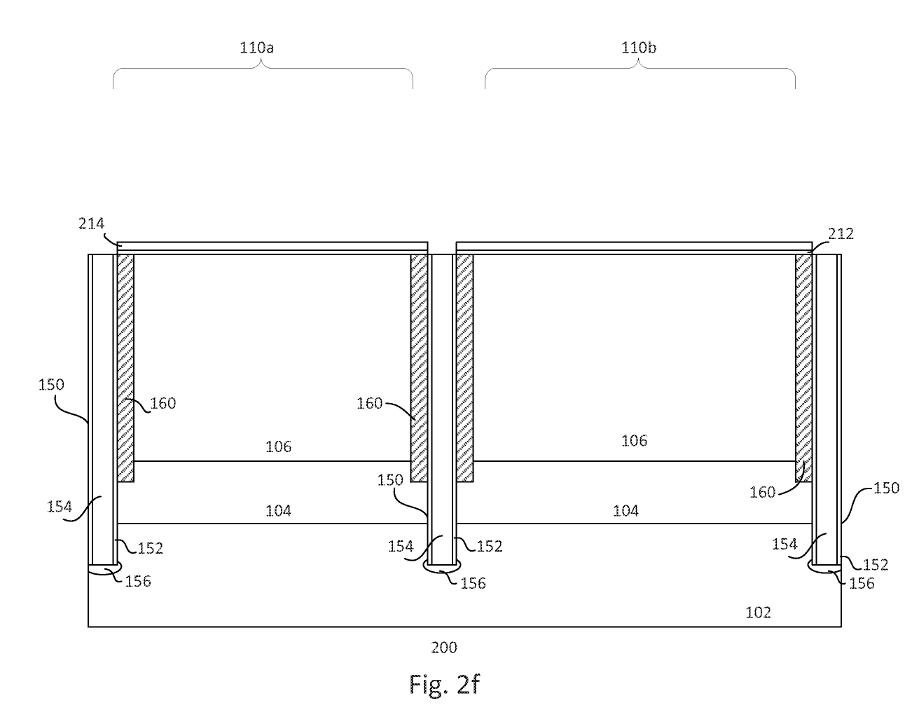

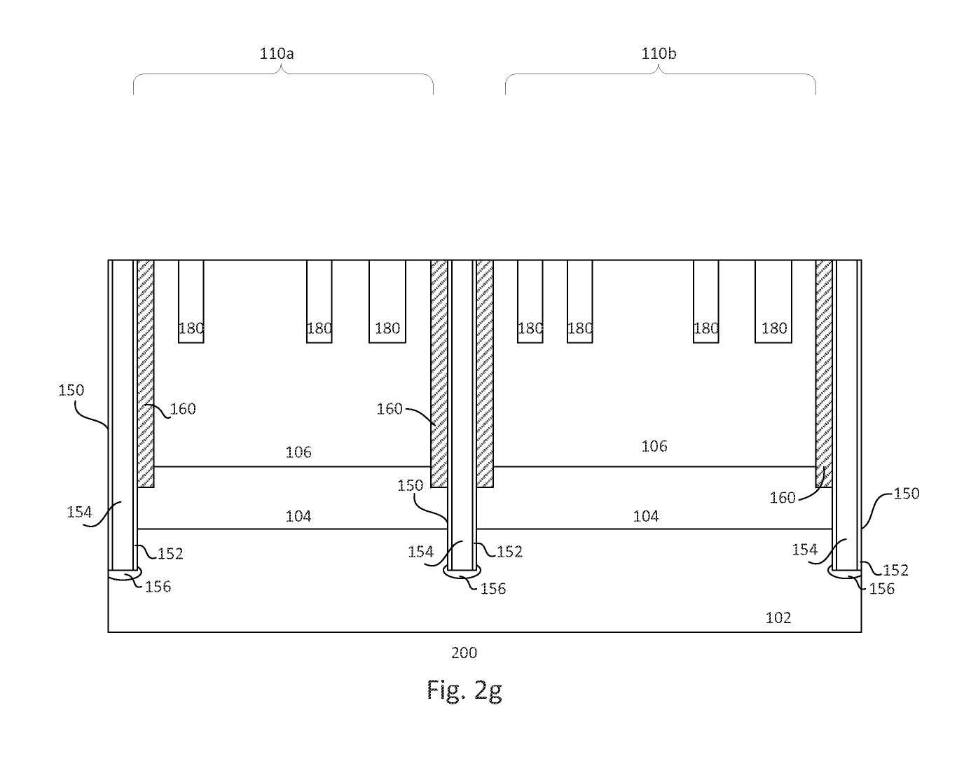

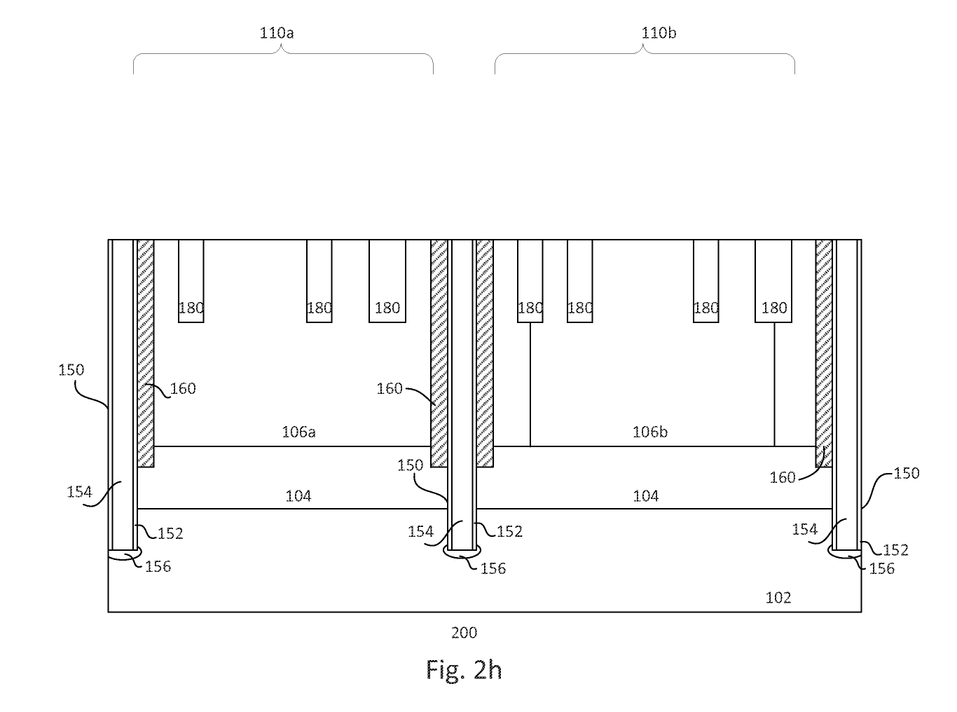

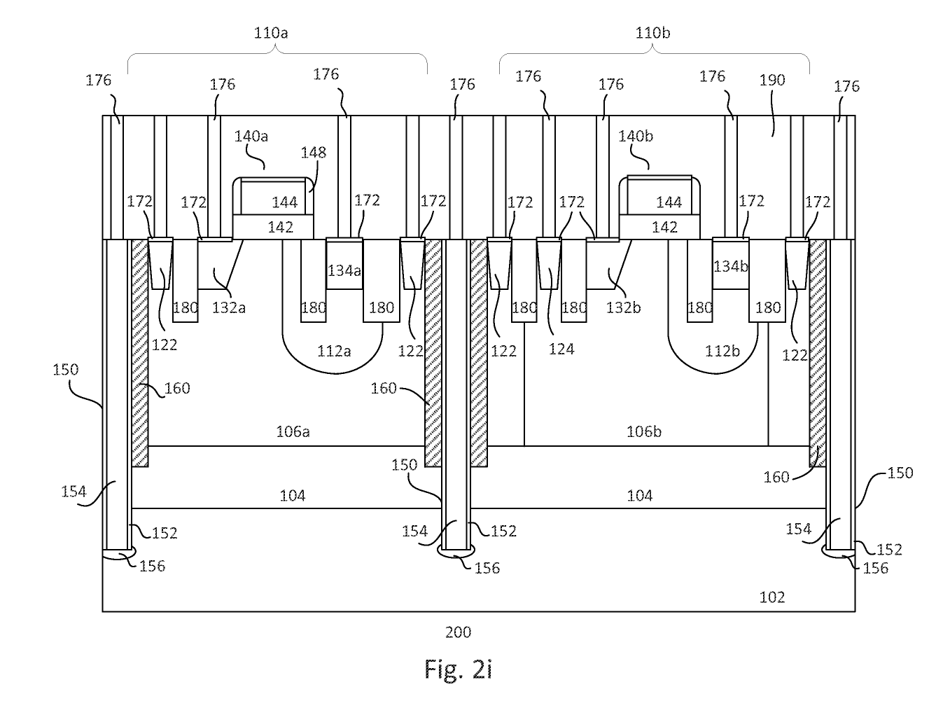

FIGS. 2a-2i show cross-sectional views of an embodiment of a process for forming a device 200. The device, for example, is similar to that described in FIG. 1a. As such, common elements may not be described or described in detail. Referring to FIG. 1a, a substrate 102 is provided. The substrate, in one embodiment, is a silicon substrate. The substrate may be a doped substrate, such as a lightly doped p⁻ substrate. Other suitable types of semiconductor substrate may also be useful. The substrates may be doped with other types of dopants or dopant concentrations, including undoped substrates.

As shown, at least one device region is defined on the substrate. Although one device region is shown, it is however understood that the substrate may include various types of regions (not shown). For example, the substrate may include other device regions for other types of circuitries or devices. Depending on the type of IC formed, the other device regions, for example, may include regions for different voltage devices and array region for memory devices. For example, the other device regions may include MV regions for MV devices and LV regions for LV devices and array regions. Other suitable types of device regions may also be provided.

For simplicity and illustration purpose, only one device region is shown. In one embodiment, the device region is a HV region. The device region, for example, serves as a device region for high voltage transistors. The HV device region, in one embodiment, includes first sub-region 110a and second sub-region 110b. Other suitable number or types of regions or sub-regions may also be included in the HV device region. For illustration purpose, the high voltage transistors, for example, include LDMOS transistors. Other suitable types of high voltage transistors may also be useful. As an example, the first sub-region includes a first polarity type LDMOS transistor 140a while the second sub-region includes a second polarity type LDMOS transistor 140b which will be described later. For example, the first polarity type LDMOS is a LDPMOS transistor while the second polarity type LDMOS is a LDNMOS transistor. The first and second sub-regions are prepared for devices operating in high voltage ranges, for example, at a voltage of about 30 V. Other suitable voltage values may also be useful.

Referring to FIG. 2a, a buried layer 104 is formed in a top portion of the substrate 102. For example, an ion implantation process which includes a blanket second polarity type ion implantation is performed to form a substantially continuous second polarity type buried layer 104 in top portion of the substrate 102, The buried layer, for example, is a heavily doped region with second polarity type dopants for a first polarity type substrate. For example, the buried layer is a n-type buried layer for a p-type substrate. For example, antimony is used to form the heavily doped n-type (N+) buried layer in a dose range of about 1E15-1E16/cm² at energy of about 50-200 KeV. Other suitable implant parameters may also be useful. The depth of the buried layer is, for example, about 1-5 μm. Other suitable depth dimensions may also be useful.

The process continues by growing an epitaxial layer 106 over the buried layer. The top surface of the epitaxial layer may be referred to as a top surface of the substrate. The epitaxial layer, in one embodiment, is a second polarity type epitaxial layer. For example, the epitaxial layer is a n-type epitaxial layer grown on the n-type buried layer. In an alternate embodiment, the epitaxial layer is a first polarity type epitaxial layer, such as p-type epitaxial layer grown on the n-type buried layer. The dopant concentration of the epitaxial layer is higher than the dopant concentration of the substrate. For example, the dopant concentration of the epitaxial layer may be, for example, about 1E11-1E13/cm². The thickness of the epitaxial layer is, for example, about 5-15 μm. Other suitable dopant concentration and thickness dimensions for the epitaxial layer may also be useful.

In one embodiment, the process continues to form DTI regions. In one embodiment, the depth of the DTI region may be defined by a two-step etch process. Referring to FIG. 2b, a patterned hard mask is disposed on the substrate. The hard mask may be a hard mask stack which includes a pad oxide layer 212 and a pad nitride layer 214. The pad oxide may be formed by thermal oxidation while the pad nitride may be formed by chemical vapor deposition (CVD). The pad nitride or upper layer of the mask stack serves as the mask while the pad oxide promotes adhesion of the upper layer to the substrate. Other suitable types of hard mask or forming techniques may also be useful.

The patterned hard mask is used to etch the epitaxial layer, buried layer and substrate to form deep isolation trenches 251 having a first depth D_{I}. The substrate exposed by openings in the hard mask stack, for example, are removed by a reactive ion etch (RIE). Patterning the hard mask may be achieved by using a photoresist mask 216. For example, a photoresist is patterned exposing it with an exposure source using a reticle with the desired pattern. After exposure, the photoresist is developed , transferring the pattern of the reticle to the photoresist. The patterned photoresist is then used as an etch mask to pattern the hard mask. D_{I}, in one embodiment, extends from top surface of the substrate and passes through the epitaxial layer to a portion of the buried layer 104. D_{I} is, for example, about 7 μm deep from the top surface of the substrate defined by top surface of the epitaxial layer 106. Other suitable depth dimensions for Di may also be useful.

Referring to FIG. 2c, the process continues to form sinker tap regions. In one embodiment, an ion implantation process is performed to form the sinker tap regions. The implant, for example, is a tilt angled implant. The implant, for example, serves to form sinker tap regions 260 in the exposed epitaxial and buried layer portions surrounding the trenches 251 in the first and second sub-regions. In one embodiment, the implant is self-aligned and may dope the exposed substrate portions to form the sinker tap regions without the need of an implant mask. Second polarity type dopants, such as phosphorus, are implanted into the substrate to form the sinker tap regions in the first and second sub-regions. The implant dose may be about 1E15-1E16/cm² and the implant energy may be about 50-200 KeV. Other suitable implant parameters may also be useful. In one embodiment, the implant is angled to form sinker tap regions which surrounds the sides and bottom of the deep trenches 251 having D_{I}. For example, the implant is performed at about 7 degree with reference to the top surface of the substrate. Other angled implants may also be useful. As shown, the sinker tap regions extend from top surface of the substrate and beyond the bottom of the deep isolation trenches having D_{I}. The depth of the sinker tap region, for example, includes any sui table depth dimensions as long as it extends into a portion of the buried layer and electrically connects to the buried layer.

The process continues to perform a second etch process to extend the depth of the deep isolation trench 251 to a final depth D_{I} as shown in FIG. 2d. For example, a RIE process is performed to extend the depth of the deep isolation trench 251 to D_{F}. Other suitable techniques for forming the deep isolation trenches may also be used. D_{F}, in one embodiment, extends beyond the buried layer 104 and into a portion of the first type substrate 102. D_{F} is, for example, about 28 μm deep from the top surface of the substrate defined by top surface of the epitaxial layer 106. Other suitable depth dimensions for DF may also be useful. As shown, the sinker tap regions 160 partially surrounds the deep isolation trench 251 having D_{F}. The photoresist 216 is removed after performing the second etch process. The photoresist is removed, for example, by ashing. Other suitable techniques for removing the photoresist may also be useful.

A dielectric layer is deposited on the substrate and lining sidewalls and bottom of the deep isolation trenches 251 and sidewalls and top of the patterned hard mask. The dielectric layer, for example, may be silicon oxide. Other suitable types of dielectric material, such as silicon nitride, may also be used. The dielectric layer may be formed by CVD. The dielectric layer may also be formed using other techniques. The thickness for the dielectric layer may be, for example, 2-6 kÅ. Other suitable thickness for the dielectric layer may also be useful. The thickness, for example, should be sufficient to sustain the highest voltage between second type buried layer and DTI. For example, the second type buried layer is connected to VDD while DTI is connected to first polarity type substrate and Vss. An anisotropic etch, such as RIE, may be performed to remove horizontal portions of the dielectric layer, leaving dielectric layer 152 lining on the sidewalls of the deep isolation trenches and patterned hard mask stack as shown in FIG. 2e. As shown, the bottom of the DTI is disposed within and coupled to the first polarity type substrate.

A channel stop region 156 is optionally formed at exposed portion of the substrate at the bottom of the deep isolation trenches as shown in FIG. 2e, The channel stop region, for example, is formed by an ion implantation process. The channel stop region includes p-type dopants with concentration of about 1E15-1E16/cm². Other suitable concentration may also be useful.

A conducting material 154 is provided on the substrate and fills the deep isolation trenches 251. The conducting material, for example, may be a polysilicon layer. The polysilicon layer, for example, may be highly doped with first polarity type dopants. For example, the polysilicon layer may be a highly p-doped polysilicon layer. The conducting material may be formed by, for example, CVD. Other suitable materials and techniques may be used for the conducting material. Excess conducting material may be removed by chemical mechanical polishing (CMP) process, followed by an etch back process such that top surface of the DTI regions 150 is substantially coplanar with top surface of the substrate as shown in FIG. 2f.

In one embodiment, the process continues to remove the hard mask. In one embodiment, the pad nitride layer 214 is removed by, for example, a wet etch selective to the pad oxide layer 212 and materials of the DTI regions. Other suitable techniques of removing the pad nitride layer may also be useful. A stripping process may be performed to remove the remaining pad oxide layer to expose the top surface of the substrate. The pad oxide layer, for example, may be removed by a wet etch process, such as HF. Other suitable techniques may be employed for the stripping process.

The process continues to form isolation regions, such as STI regions 180 as shown in FIG. 2g. Various processes can be employed to form the STI regions. For example, the substrate can be etched using etch and mask techniques to form isolation trenches which are then filled with dielectric materials such as silicon oxide. CMP can be performed to remove excess oxide and provide a planar substrate top surface. Other processes or materials can also be used to form the STI regions 180. The depth of the STI regions may be, for example, about 2000-5000 Å. Other suitable depths for the STI regions may also be useful.

As shown in FIG. 2h, first and second device wells 106a and 106b are defined in the first and second sub-regions. The device well serves as a body well for a transistor. In one embodiment, a second device well 106b is formed within the epitaxial layer 106. The second device well 106b, for example, includes first polarity type dopants. In one embodiment, the second device well is a lightly doped device well. For example, the dopant concentration of the second device well is, for example, about 1E12-1E14/cm². The depth of the second device well, for example, is smaller or the same as the thickness of the epitaxial layer. Other suitable depths for the second device well may also be useful.

The process continues to form HV transistors on the substrate. For example, the process continues to form various elements of the HV transistors. For illustration purpose, the process continues to complete formation of HV transistors, such as LDMOS transistors 140a-140b as shown in FIG. 2i. It is understood that other suitable types of HV transistors may be formed. The process to form the LDMOS transistors, for example, includes forming drift regions, gates, sidewall spacers adjacent to the gate sidewalks and source/drain regions of the HV transistors. Various suitable techniques to form elements of the LDMOS transistors may be employed and will not be described in detail. The process may continue to form metal silicide contacts on exposed substrate regions, followed by forming a dielectric layer 190 on the substrate, covering the transistors and top surface of the substrate. Contact plugs 176 may be formed in the PMD layer. The contacts plugs, for example, are coupled to contact regions of the transistor. The process continues to complete forming the device. For example, additional processes may be performed to complete the device. Such processes may include forming additional interconnect metal levels, final passivation, dicing, packaging and testing.

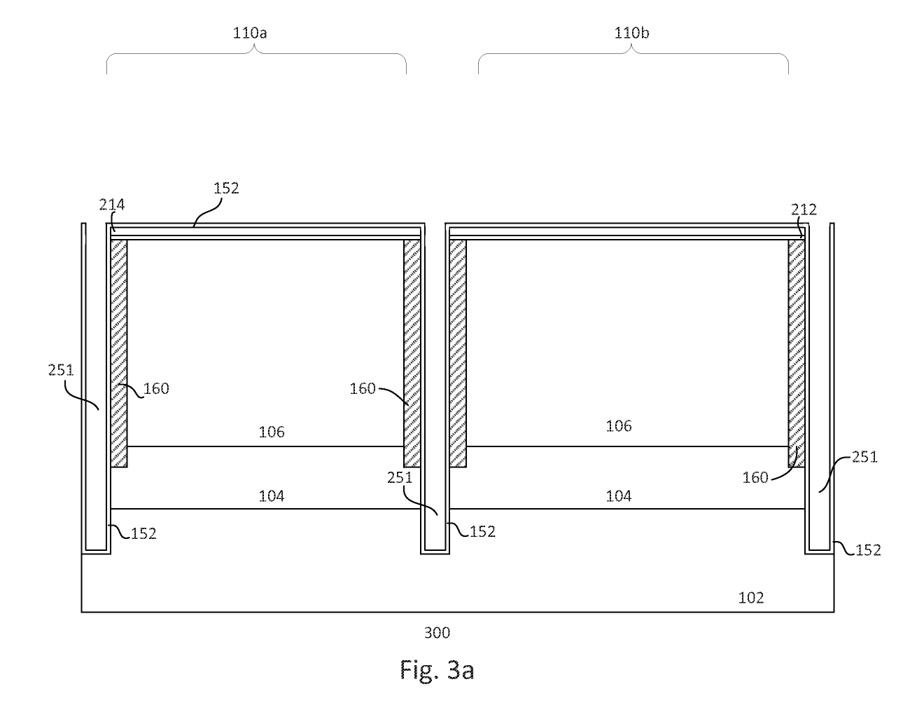

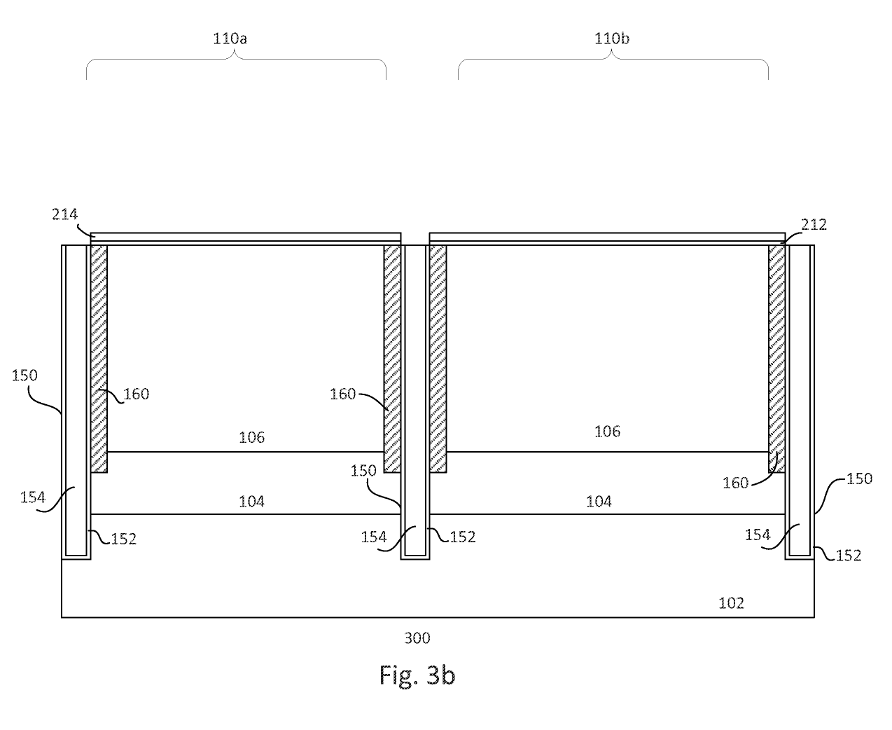

-FIGS. 3a-3b show cross-sectional views of another embodiment of a process 300 for forming a device or 1C. The device and process is similar to that described in FIGS. 2a-2i. As such, common features or features having the same reference numerals may not be described or described in detail. Referring to FIG. 3a, a partially processed substrate is provided. The substrate, as shown, is at the stage of processing as described in FIG. 2d. For example, deep trench isolation 251 having final depth D_{F}which extends beyond the buried layer 104 and into a portion of the first type substrate has been formed. As shown, sinker tap region partially surrounds the sides of the deep trenches 251 and extends from top surface of the substrate defined by top surface of the epitaxial layer into a portion of the buried layer and electrically connects to the buried layer 104.

Referring to FIG. 3a, the process continues to form a dielectric layer 152 on the substrate and lining sidewalls and bottom of the deep isolation trenches 251 and sidewalks and top of the patterned hard mask. The dielectric layer and its forming technique is the same as that described in FIG. 2e. The partially processed substrate in FIG. 3a differs from the partially processed substrate in FIG. 2e in that no channel stop region is formed at the bottom of the deep isolation trenches 251 and the dielectric layer 152 remains on the bottom of the deep isolation trenches. In such case, the deep trench isolation structure is formed without serving as the substrate tap. As such, a first polarity type substrate tap (not shown) will be separately formed at other area in the substrate using suitable implant process.

The process continues to fill the deep isolation trenches 251 with a conducting material 154. The conducting material and its forming techniques are the same as that described in FIG. 2f. Excess isolation material may be removed by CMP process followed by an etch back process such that top surface of the DTI regions is substantially coplanar with top surface of the substrate as shown in FIG. 3b. The process continues to remove the hard mask, define STI regions, device and forming HV transistors, etc. For example, the process continues as described in FIG. 2g and onwards. For instance, the process performs the steps as described from FIGS. 2g and onwards until a device such as that shown in FIG. 1b is formed.

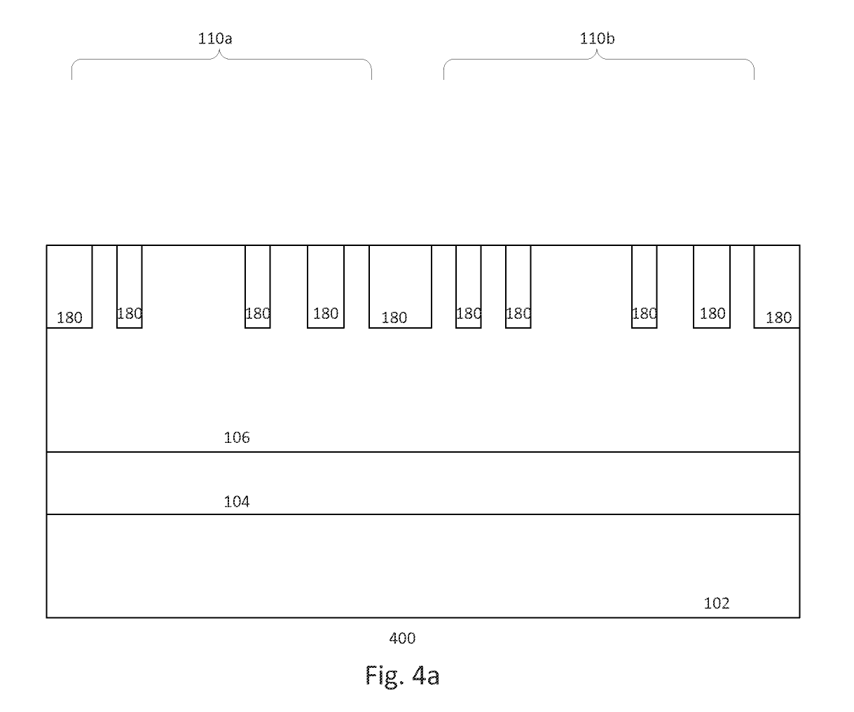

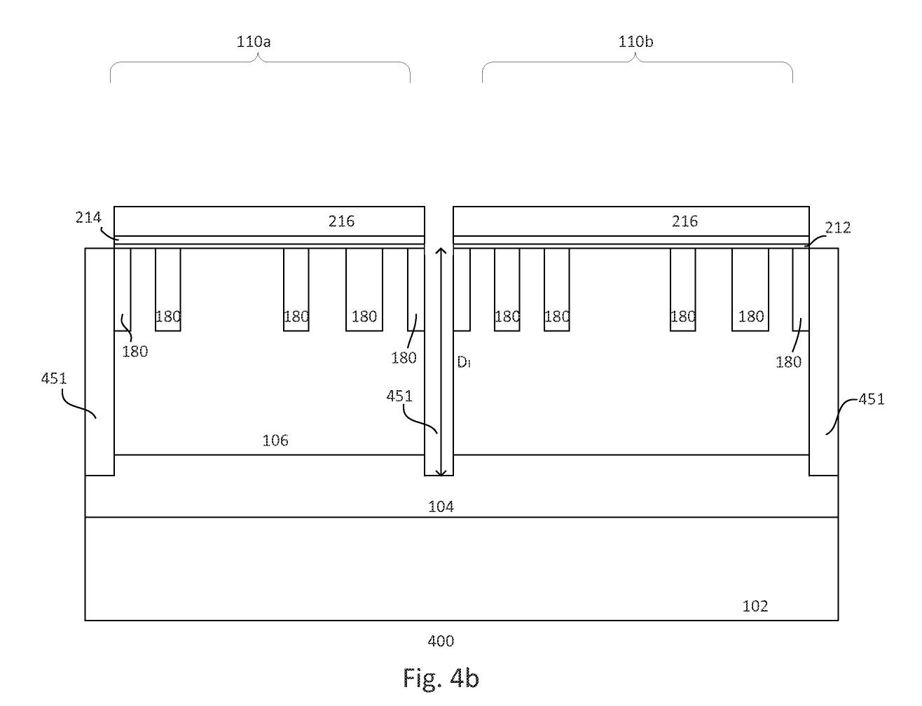

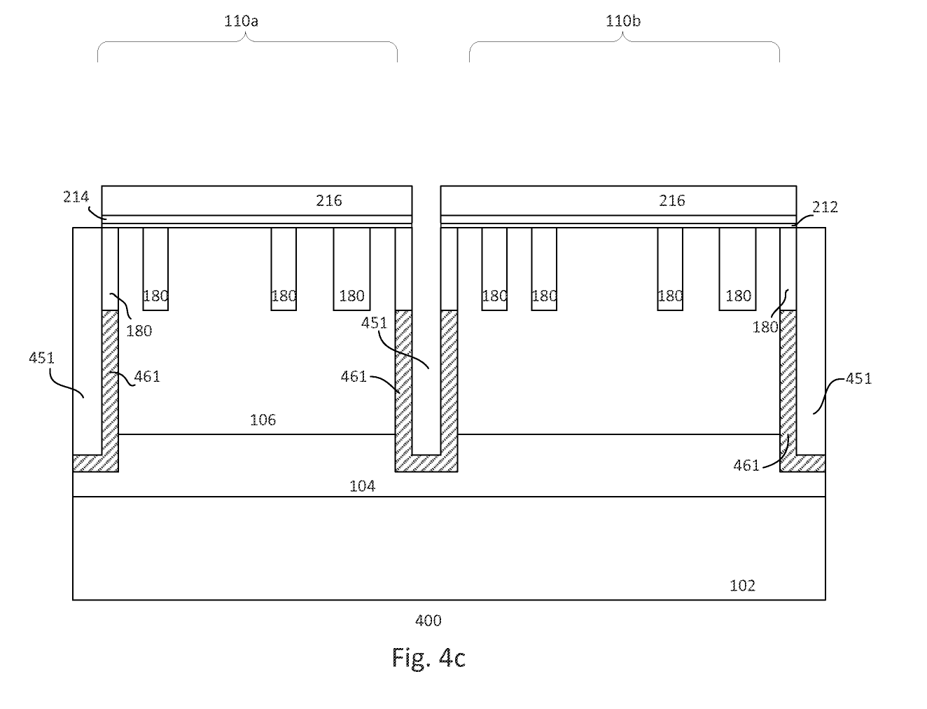

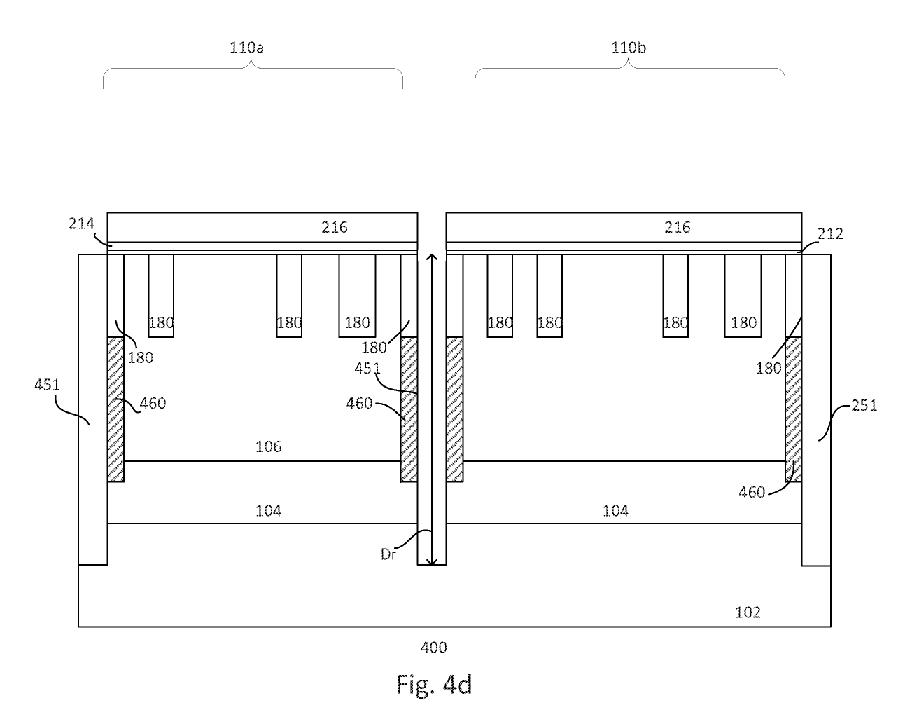

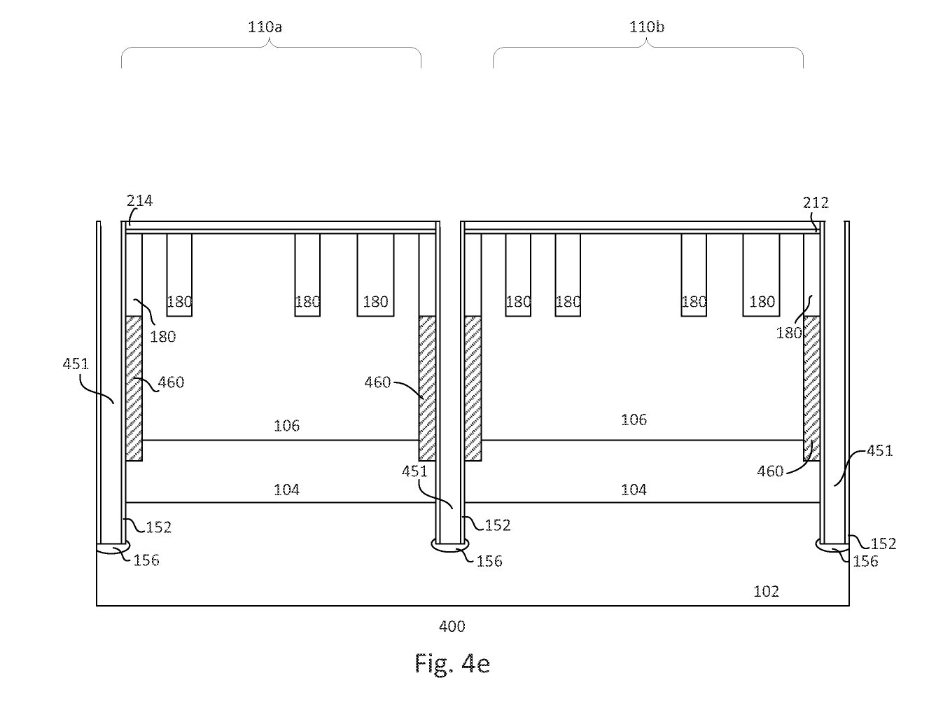

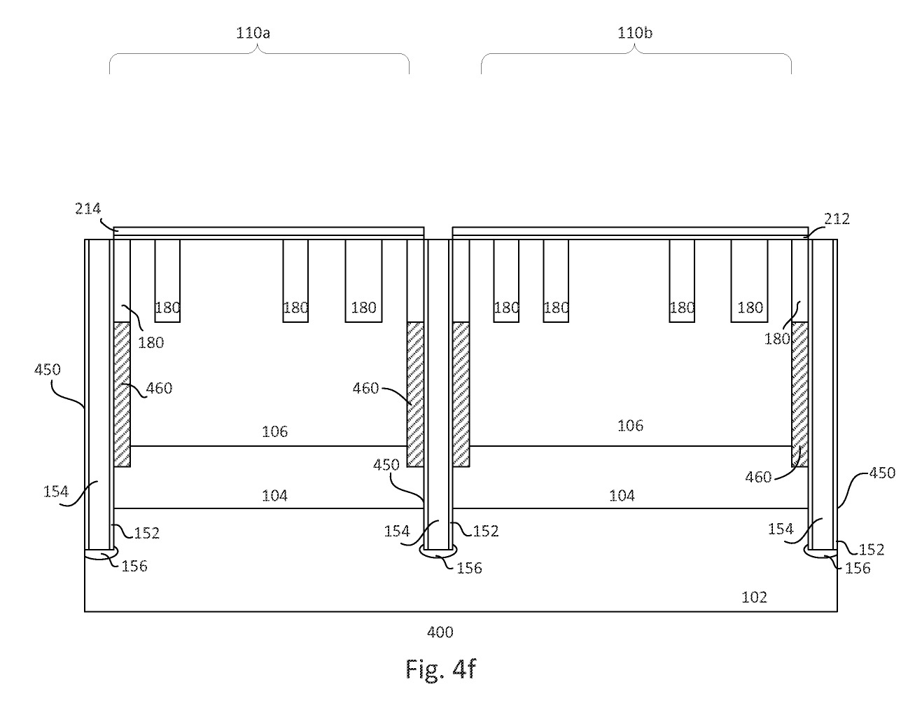

FIGS. 4a-4f show cross-sectional views of another embodiment of a process 400 for forming a device or IC. The process is similar to that described in FIGS. 2a-2i. As such, common features or features having the same reference numerals may not be described or described in detail. Referring to FIG. 4a, a partially processed substrate is provided. The substrate, as shown, is at the stage of processing as described in FIG. 2a. For example, a substrate 102 is provided and buried layer 104 is formed in a top portion of the substrate while an epitaxial layer 106 is grown over the buried layer.

In one embodiment, the process continues to define STI regions 180 in the epitaxial layer 106 as shown in FIG. 4a. The materials and techniques for forming the STI regions are the same as that described in FIG. 2g. After forming the STI regions, the process continues to form deep isolation trenches 451 having a first depth D_{I} as shown in FIG. 4b. For example, a patterned hard mask having pad oxide and pad nitride layers 212 and 214 are formed on top surface of the substrate. Techniques for forming the deep isolation trenches 451 are the same as that described in FIG. 2b. Referring to FIG. 4b, the patterned hard mask, in one embodiment, includes openings which expose a portion of some of the STI regions. The deep isolation trenches 451, in one embodiment, extends from top surface of some of the STI regions exposed by the patterned hard mask and passes through the exposed STI regions 180 and the epitaxial layer 106 to a portion of the buried layer 104 as shown in FIG. 4b.

Referring to FIG. 4c, the process continues to form sinker tap regions. In one embodiment, an ion implantation process is performed to form the sinker tap regions. The implant, for example, is a tilt angled implant. The implant, for example, serves to form sinker tap regions 461 in the exposed epitaxial layer and buried layer surrounding the trenches 451 in the first and second sub-regions. In one embodiment, the implant is self-aligned and may dope the exposed epitaxial and buried layer portions to form the sinker tap regions without the need of an implant mask. Second polarity type dopants, such as phosphorus, are implanted into the substrate to form the sinker tap regions in the first and second sub-regions. The implant dose, for example, may be about 1E15˜1E16/cm² and the implant energy maybe about 50-200 KeV. Other suitable implant parameters may also be useful. In one embodiment, the implant is angled to form sinker tap regions which surround the sides of the deep isolation trenches below the STI regions and bottom of the deep trenches having D_{I} as shown in FIG. 4c. For example, the implant is performed at about 7 degree with reference to the top surface of the substrate. Other angled implants may also be useful. As shown , the sinker tap regions extend from bottom of the STI regions and beyond the bottom of the deep trench isolation having D_{I}.

The process continues to perform a second etch process to extend the depth of the deep isolation trench 451 to a final depth D_{F} as shown in FIG. 4d. The depth D_{F} and the second etch process and parameters are the same as that described in FIG. 2d. As shown, the sinker tap regions 460 extend from bottom of the STI regions and into a portion of the buried layer 104. Dielectric layer lining the sidewalks and bottom of the deep isolation trenches and sidewalks and top of the patterned hard mask is formed. A RIE process is performed to remove horizontal portions of the dielectric layer, leaving the dielectric layer 152 lining sidewalls of the deep isolation trenches and patterned hard mask as shown in FIG. 4e. A channel stop region 156 may be optionally formed at exposed portion of the substrate at the bottom of the deep isolation trenches as shown in FIG. 4e. Materials and techniques for forming the dielectric layer 152 and the channel stop region 156 are the same as that described in FIG. 2e.

The process continues to complete formation of the DTI region 450, For example, the process proceeds with the formation of conducting material 154 filling the deep isolation trenches 451 as shown in FIG. 4f. Conducting material and forming techniques are the same as that described in FIG. 2f. The process continues to remove the hard mask, define the device and forming HV transistors, etc. For example, the process continues as described in FIG. 2h and onwards. For instance, the process performs the steps as described from FIG. 2h onwards until a device such as that shown in FIG. 1c is formed.

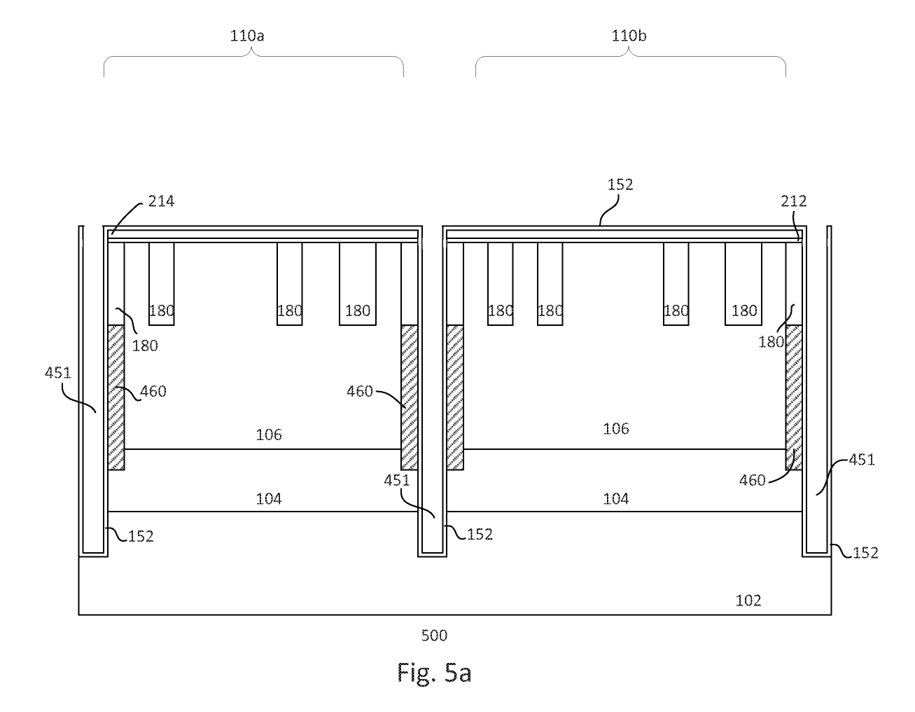

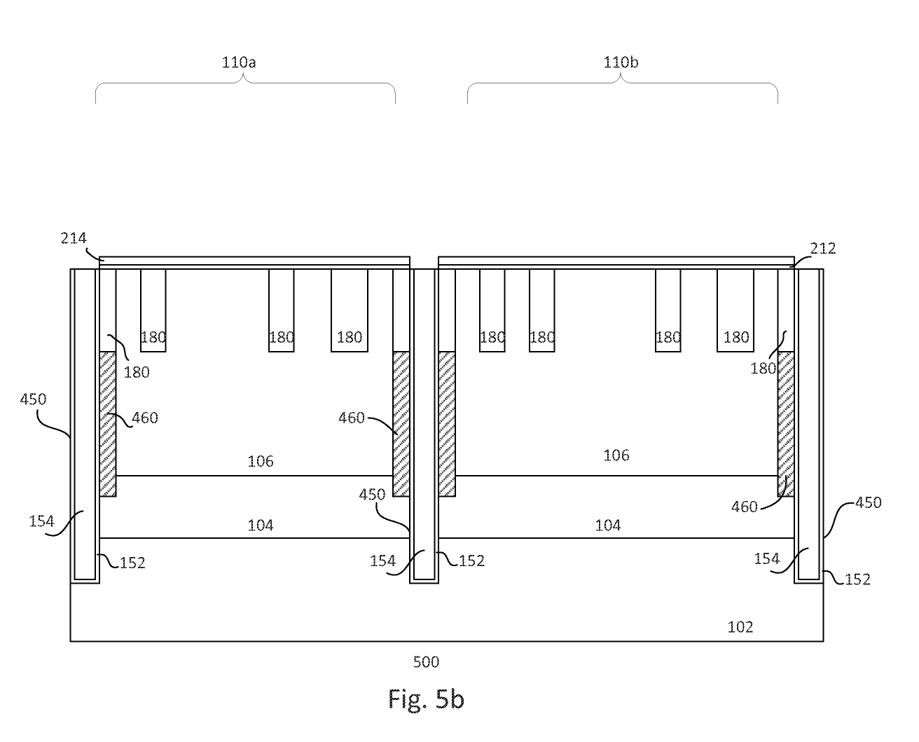

FIGS. 5a-5b show cross-sectional views of another embodiment of a process 500 for forming a device or IC. The device and process is similar to that described in FIGS. 2a-2i and FIGS. 4a-4f. As such, common features or features having the same reference numerals may not be described or described in detail. Referring to FIG. 5a, a partially processed substrate is provided. The substrate, as shown, is at the stage of processing as described in FIG. 4d. For example, deep isolation trench 451 having final depth D_{F} which extends beyond the buried layer 104 and into a portion of the first type substrate has been formed. As shown, sinker tap regions 460 which partially surround the sides of the deep isolation trenches below the STI regions and extend from bottom of the STI regions into a portion of the buried layer and electrically connects to the buried layer are formed.

Referring to FIG. 5a, the process continues to form a dielectric layer 152 on the substrate and lining sidewalls and bottom of the deep isolation trenches 451 and sidewalls and top of the hard mask stack. The dielectric layer and its forming technique is the same as that described in FIG. 2e. The partially processed substrate in FIG. 5a differs from the partially processed substrate in FIG. 4e in that no channel stop region is formed at the bottom of the deep isolation trenches 451 and dielectric layer 152 remains on the bottom of the deep isolation trenches. In such case, the deep trench isolation structure is formed without serving as the substrate tap. As such, a first polarity type substrate tap (not shown) will be separately formed at other area in the substrate using suitable implant process.

The process continues to fill the deep isolation trenches 451 with a conducting material 154. The conducting material and its forming techniques are the same as that described in FIG. 2f. Excess conducting material may be removed by CMP process, followed by an etch back process such that top surface of the DTI regions is substantially coplanar with top surface of the substrate as shown in FIG. 5b. The process continues to remove the hard mask, define the device and forming HV transistors, etc. For example, the process continues as described in FIG. 2h and onwards. For instance, the process performs the steps as described from FIG. 2h and onwards until a device such as that shown in FIG. 1d is formed.

The processes as described in FIGS. 2a-2i, FIGS. 3a-3b, FIGS. 4a-4f and FIGS. 5a-5b result in advantages. The processes as described allow configuration of the DTI regions, sinker tap regions, the buried layer and the epitaxial layer such as that shown in FIGS. 1a-1d to be formed and integrated in the same IC without the need for additional masking step. For example, the buried layer and the DTI regions are formed to avoid punch-through breakdown. Moreover, the configuration of these regions and layers effectively avoid latch up problem and effectively isolate the high voltage LDMOS transistors from other device regions. Furthermore, the processes enable the implant to form the sinker tap regions to be self-aligned without the need of an additional or separate implant mask. This simplifies the manufacturing process and allow various devices with different voltages to be integrated or formed together with reduced cost. Also, the sinker tap region can also serve as drain tap for VDMOS (not shown) in IC.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description , an d all changes that come within the meaning and range of equivalency of the claims are intended to be embraced therein.

What is claimed is:

1. A method for forming a device comprising:
providing a substrate with lightly doped first polarity type dopants; forming a buried layer with heavily doped second polarity type dopants in a top portion of the substrate;
forming an epitaxial layer over the buried layer;
forming deep trench isolation (DTI) regions which extend from top surface of the epitaxial layer to a portion of the substrate, wherein the DTI regions isolate different buried regions defined in the buried layer;
forming sinker tap regions which at least partially surround sides of the DTI regions and extend from the epitaxial layer into a portion of the buried layer, wherein the sinker tap region connects sinker taps to the buried layer;
forming shallow trench isolation (STI) regions in the epitaxial layer; and
forming at least one transistor on the epitaxial layer.

2. The method of claim 1 wherein forming the buried layer comprises:
performing a blanket second polarity type ion implantation to form a substantially continuous second polarity type buried layer in the top portion of the substrate.

3. The method of claim 1 wherein forming the DTI regions comprising:
performing a first etch to form deep isolation trenches having a first depth which extends to the top surface of the epitaxial layer to a portion of the buried layer; and
performing a second etch process to extend the first depth of the deep isolation trenches to a final depth which extends beyond the buried layer and into a portion of the substrate.

4. The method of claim 3 wherein:
the sinker tap regions is formed after performing the first etch to form the deep isolation trenches; and
the sinker tap regions are formed by performing a tilt angled implant and the tilt angled implant is self-aligned without the need of an implant mask.

5. The method of claim 4 wherein the sinker tap regions extend from the top surface of the epitaxial layer and beyond bottom of the deep isolation trenches having the first depth.

6. The method of claim 5 wherein forming the DTI regions comprises:
forming a dielectric layer lining sidewalls and bottom of the deep isolation trenches having the final depth;
performing an etch to remove portion of the dielectric layer which lines the bottom of the deep isolation trenches; and
providing a conducting material to fill the deep isolation trenches.

7. The method of claim 6 wherein the conducting material comprises a polysilicon layer highly doped with first polarity type dopants.

8. The method of claim 6 wherein forming the DTI regions comprises:
performing a chemical mechanical polishing (CMP) to remove excess conducting material; and
performing an etch back process such that the DTI regions comprise a substantially coplanar top surface with the top surface of the epitaxial layer.

9. The method of claim 6 comprising:
forming a channel stop region at exposed portion of the substrate at the bottom of the deep isolation trenches having the final depth.

10. The method of claim 5 wherein forming the DTI regions comprises:
forming a dielectric layer lining sidewalls and bottom of the deep isolation trenches having the final depth; and
providing a conducting material to fill the deep isolation trenches.

11. The method of claim 10 wherein the conducting material comprises a polysilicon layer highly doped with first polarity type dopants and forming the DTI regions comprises:
performing a chemical mechanical polishing (CMP) to remove excess conducting material; and
performing an etch back process such that the DTI regions comprise a substantially coplanar top surface with the top surface of the epitaxial layer.

12. The method of claim 2 wherein the STI regions are formed prior to forming the DTI regions.

13. The method of claim 12 wherein forming the DTI regions comprising:
performing a first etch to form deep isolation trenches having a first depth which extend from top surface of some of the STI regions and pass through these STI regions and the epitaxial layer to a portion of the buried layer; and
performing a second etch process to extend the first depth of the deep isolation trenches to a final depth which extends beyond the buried layer and into a portion of the substrate.

14. The method of claim 13 wherein:
the sinker tap regions is formed after performing the first etch to form the deep isolation trenches; and
the sinker tap regions are formed by performing a tilt angled implant and the tilt angled implant is self-aligned without the need of an implant mask,

15. The method of claim 14 wherein the sinker tap regions surround sides of the deep isolation trenches below the STI regions and bottom of the deep isolation trenches having the first depth.

16. The method of claim 15 wherein forming the DTI regions comprises:
forming a dielectric layer lining sidewalls and bottom of the deep isolation trenches having the final depth;
performing an etch to remove portion of the dielectric layer which lines the bottom of the deep isolation trenches; and
providing a conducting material to fill the deep isolation trenches.

17. The method of claim 15 wherein forming the DTI regions comprises:
forming a dielectric layer lining sidewalls and bottom of the deep isolation trenches having the final depth; and
providing a conducting material to fill the deep isolation trenches.

18. A device comprising:
a substrate with lightly doped first polarity type dopants;
a buried layer with heavily doped second polarity type dopants disposed in a top portion of the substrate;
an epitaxial layer disposed over the buried layer;
deep trench isolation (DTI) regions which extend from top surface of the epitaxial layer to a portion of the substrate, wherein the DTI regions isolate different buried regions defined in the buried layer;
sinker tap regions which at least partially surround sides of the DTI regions and extend from the epitaxial layer into a portion of the buried layer, wherein the sinker tap region connects sinker taps to the buried layer;
shallow trench isolation (STI) regions disposed in the epitaxial layer; and
at least one transistor disposed on the epitaxial layer.

19. The device of claim 18 wherein the sinker tap regions extend from a top surface of the epitaxial layer and beyond a top surface of the buried layer.

20. The device of claim 18 wherein the DTI regions extend from top surface of some of the STI regions and pass through these STI regions and the epitaxial layer to a portion of the buried layer; and
the sinker tap regions surround sides of the DTI regions below the STI regions and extend beyond a top surface of the buried layer.
